(19) United States
(12) Patent Application Publication
(10) Pub. No.: US 2011/0199330 A1
(43) Pub. Date: Aug. 18, 2011

(54) SURFACE CAPACITIVE TOUCH PANEL AND ITS FABRICATION METHOD

(76) Inventors: Ching-Fu Hsu, Tai Chung County (TW); Chih-Chang Lai, Tai Chung County (TW); Sherry Lin, (US); Fa-Chen Wu, (US)

(21) Appl. No.: 13/018,901

(22) Filed: Feb. 1, 2011

(30) Foreign Application Priority Data
Feb. 12, 2010 (TW) 099104565
Dec. 24, 2010 (TW) 099145784

(51) Int. Cl. G06F 3/045; H05K 3/00

(52) U.S. Cl. 345/174; 29/829; 178/18.06

(57) ABSTRACT

A surface capacitive touch panel includes a transparent substrate, a decorative layer, a metal trace pattern layer, and a passivation layer. The decorative layer and the capacitive sensing electrode layer are formed on the transparent substrate. The metal trace pattern layer is formed on the capacitive sensing electrode layer. The decorative layer is disposed at a position substantially overlapping the metal trace pattern layer.

### BACKGROUND OF THE INVENTION

a. Field of the Invention

The invention relates to a surface capacitive touch panel and a method for fabricating the surface capacitive touch panel.

b. Description of the Related Art

Nowadays, capacitive touch panels are grouped into two categories, namely projected capacitive touch panels and surface capacitive touch panels. Though a surface capacitive touch panel fails to perform multi-touch operations due to its driving architecture, it has a simplified structure and reduced fabrication costs compared with a projected capacitive touch panel.

FIG. 1 shows a schematic diagram illustrating a conventional surface capacitive touch panel. As shown in FIG. 1, the top surface and the bottom surface of a glass substrate 11 are separately coated with a conductive coating 12 and a conductive coating 13. The material of the conductive coatings 12 and 13 may be, for example, indium tin oxide (ITO). Then, a silver trace layer 14 is formed on the conductive coating 12 by screen printing. Further, a hard coating layer 15 is provided to serve insulating and protection purposes, and an anti-glare coating 16 is provided to prevent light reflection and glare. However, as the above surface capacitive touch panel is integrated into a mobile device, a cover glass is additionally needed to shadow metal traces and thus results in greater module thickness. Besides, the silver-trace processing tends to cause a wide border for the touch panel.

Another prior design such as Taiwan patent no. 1303835 discloses a capacitive touch panel, where an end point of a conductive wiring segment is rounded to improve the electric-field characteristic of a panel border and thereby smooth and uniform electrical lines of force. In addition, Taiwan patent no. 1288699 discloses a capacitive touch panel having a multi-layer reflective structure, where the index of refraction of stacking layers is varied to increase the entire transmittance. However, these designs all require an additional glass for protection and shadowing purposes to hence increase the overall thickness.

### BRIEF SUMMARY OF THE INVENTION

The invention provides a surface capacitive touch panel having a thin shape and a narrow panel border. The invention also provides a method for fabricating a surface capacitive touch panel to reduce film thickness, increase film thickness uniformity and improve reliability.

According to an embodiment of the invention, a surface capacitive touch panel includes a transparent substrate, a decorative layer, a capacitive sensing electrode layer, a metal trace pattern layer, and a passivation layer. The decorative layer is formed on a surface of the transparent substrate and the capacitive sensing electrode layer is formed on a first side of the transparent substrate. The metal trace pattern layer is formed on the capacitive sensing electrode layer. The decorative layer is disposed at a position substantially overlapping the metal trace pattern layer to shadow metal traces of the metal trace pattern layer. The passivation layer is formed between the transparent substrate and the capacitive sensing electrode layer.

In one embodiment, the decorative layer is a black matrix layer, the metal traces are silver traces, and the metal trace pattern layer is formed on the periphery of the capacitive sensing electrode layer.

In one embodiment, the decorative layer is made of at least one of diamond-like carbon, ceramics, ink, and photo resists.

In one embodiment, the decorative layer is formed on the first side of the transparent substrate and disposed between the transparent substrate and the capacitive sensing electrode layer.

In one embodiment, the decorative layer is formed on a second side of the transparent substrate opposite the first side.

In one embodiment, the surface capacitive touch panel further includes at least one driver chip disposed on the decorative layer.

According to another embodiment of the invention, the method for fabricating a surface capacitive touch panel includes the following steps: providing a transparent substrate; forming a coating on a surface of the transparent substrate and patterning the coating to form a decorative layer; forming a capacitive sensing electrode layer on the transparent substrate; forming a metal trace pattern layer on the capacitive sensing electrode layer, where the decorative layer is disposed at a position substantially overlapping the metal trace pattern layer to shadow metal traces of the metal trace pattern layer; and forming a first passivation layer between the transparent substrate and the capacitive sensing electrode layer.

In one embodiment, the step of forming a decorative layer includes sputtering an inorganic material on the surface of the transparent substrate to form an inorganic coating, and patterning the inorganic coating. The inorganic material includes Cr, CrOₓ, and SiO₂.

In one embodiment, the step of forming a metal trace pattern layer includes sputtering a metal layer and patterning the metal layer by using a shadow mask.

In one embodiment, the method for fabricating a surface capacitive touch panel further includes forming a passivation layer on the metal trace pattern layer to cover the metal trace pattern layer.

In one embodiment, the passivation layer is patterned by coating, exposing, developing, and post-baking.

In one embodiment, the thickness of the decorative layer is between 0.01 μm and 50 μm, the thickness of the passivation layer is between 0.1 μm and 10 μm, and the thickness of the metal trace pattern layer is between 0.1 μm and 20 μm.

According to the design of the above embodiments, since the surface-capacitive stacking layers including the decorative layer are directly formed on a transparent substrate, the transparent substrate with the decorative layer naturally functions as a cover glass, and thus a separate cover glass is not needed to thereby reduce the overall thickness of a surface capacitive touch panel. In addition, the shadowing effect of the decorative layer on the transparent substrate allows to avoid an excessively wide panel border. Besides, during the process of forming the touch sensing electrode layer on an entire plane of the transparent substrate, a polyester substrate commonly serving as a carrier is no longer needed to reduce fabrication costs. Further, in contrast to the conventional design, the stacking layers in the above embodiment are formed on a bottom surface (non-touching face) of the transparent substrate. Therefore, the requirements of anti-scratch and anti-glare are not critical, and an additional anti-scratch or anti-glare layer is no longer needed to further reduce fabrication costs. Besides, the processes used by the above embodiments are capable of reducing film thickness, increasing film thickness uniformity, and improving reliability.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 shows a schematic diagram of a conventional surface capacitive touch panel according to the prior art.

FIG. 2A shows a schematic diagram illustrating parts breakdown of a surface capacitive touch panel according to one embodiment of the invention, and FIG. 2B shows a cross-sectional schematic diagram of the parts in FIG. 2A after assembled.

FIG. 3 shows a schematic diagram illustrating a surface capacitive touch panel according to another embodiment of the invention.

FIG. 4 shows a schematic diagram illustrating a surface capacitive touch panel according to another embodiment of the invention.

FIG. 5 shows a schematic diagram illustrating a surface capacitive touch panel according to another embodiment of the invention.

### DETAILED DESCRIPTION OF THE INVENTION

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

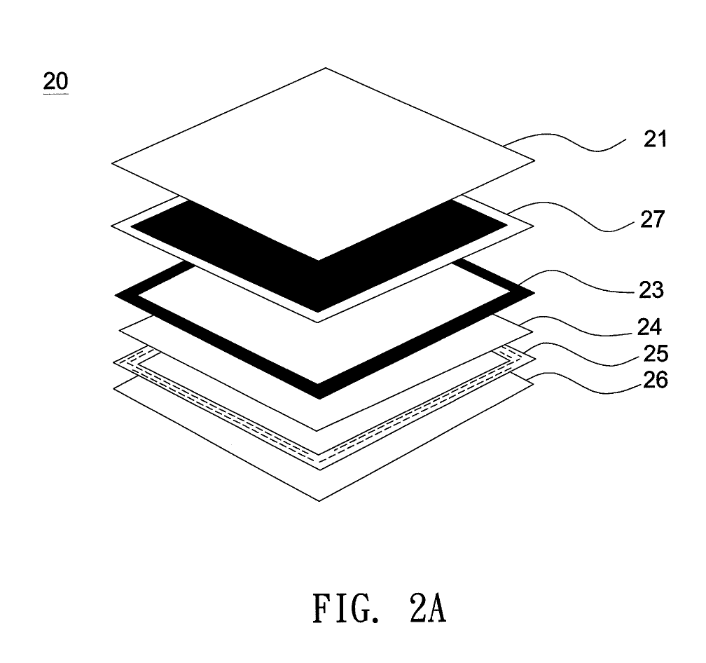

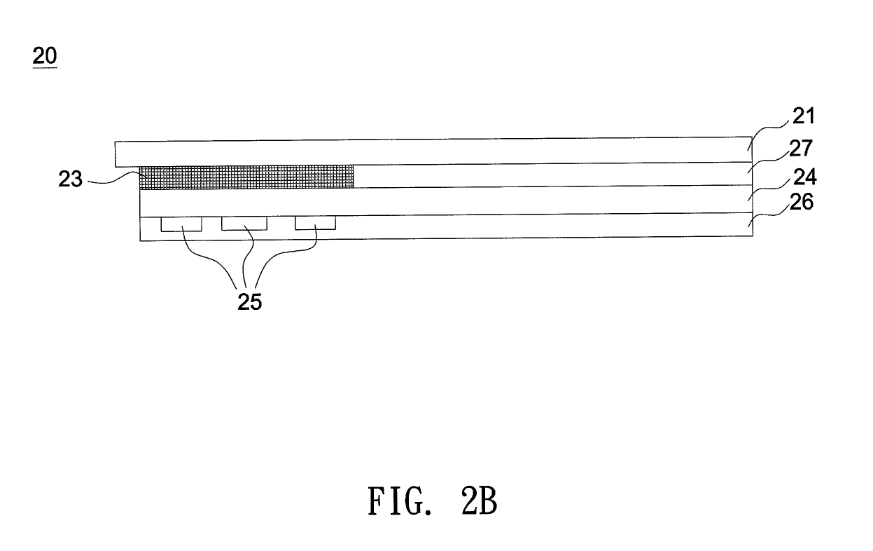

FIG. 2A shows a schematic diagram illustrating parts breakdown of a surface capacitive touch panel according to one embodiment of the invention, and FIG. 2B shows a cross-sectional schematic diagram of the parts in FIG. 2A after assembled. As shown in FIGS. 2A and 2B, the surface capacitive touch panel 20 at least includes a transparent substrate 21, a decorative layer 23, a capacitive sensing electrode layer 24, and a metal trace pattern layer 25. The decorative layer 23 is formed on a surface of the transparent substrate 21, and the capacitive sensing electrode layer 24 is formed on a first side of the transparent substrate 21. The metal trace pattern layer 25 is formed on the capacitive sensing electrode layer 24. A passivation layer 26 is formed on the metal trace pattern layer 25 and covers the metal trace pattern layer 25. Another passivation layer 27 is formed between the transparent substrate 21 and the capacitive sensing electrode layer 24 and serves as an insulation layer. In this embodiment, the decorative layer 23 and the capacitive sensing electrode layer 24 are formed on the same side of the transparent substrate 21, the capacitive sensing electrode layer 24 is substantially spread on an entire plane of the transparent substrate 21, and the metal trace pattern layer 25 may be formed on the periphery of the capacitive sensing electrode layer 24. The decorative layer 23 is disposed at a position substantially overlapping the metal trace pattern layer 25 to shadow metal traces such as silver traces in the metal trace pattern layer 25. The capacitive sensing electrode layer 24 includes, for example, a plurality of first-axis sensing pads, a plurality of second-axis sensing pads, and a plurality of connecting lines connected between these sensing pads. The decorative layer 23 only serves as a mask for shadowing metal traces and thus its composition is not limited. For example, the decorative layer 23 may be a black matrix layer, and the decorative layer may be made of at least one of diamond-like carbon, ceramics, ink, and photo resists.

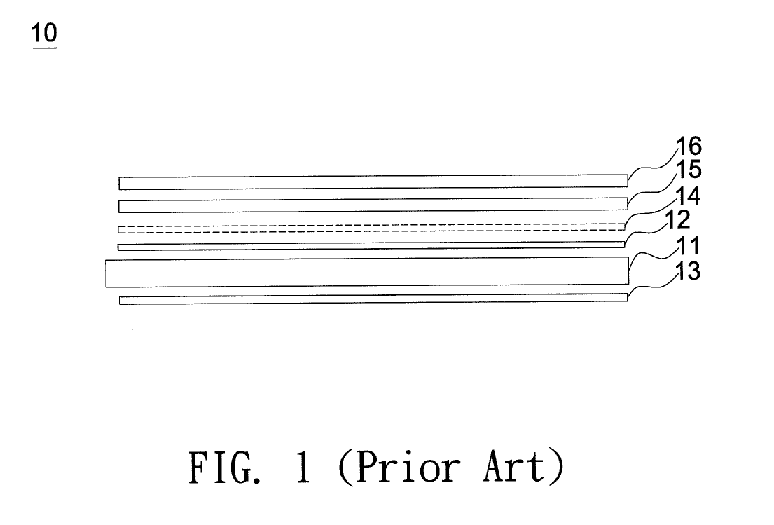

According to the above embodiment, since the surface-capacitive stacking layers including the decorative layer 23 are directly formed on the transparent substrate 21, the transparent substrate 21 with the decorative layer 23 naturally functions as a cover glass, and thus a separate cover glass is not needed to thereby reduce the overall thickness of the surface capacitive touch panel 20. In addition, the shadowing effect of the decorative layer 23 on the transparent substrate 21 allows to avoid an excessively wide panel border that often occurs as a result of metal trace processing. Besides, according to the above embodiment, during the process of forming the touch sensing electrode layer 24 on an entire plane of the transparent substrate 21, a polyester substrate commonly serving as a carrier is no longer needed to reduce fabrication costs. Further, in contrast to the conventional design shown in FIG. 1 where stacking layers are almost formed on a top surface (touching face) of the transparent substrate 11, the stacking layers in the above embodiment are formed on a bottom surface (non-touching face) of the transparent substrate 21. Therefore, the requirements of anti-scratch and anti-glare are not critical, and an additional anti-scratch or anti-glare layer is no longer needed to further reduce fabrication costs.

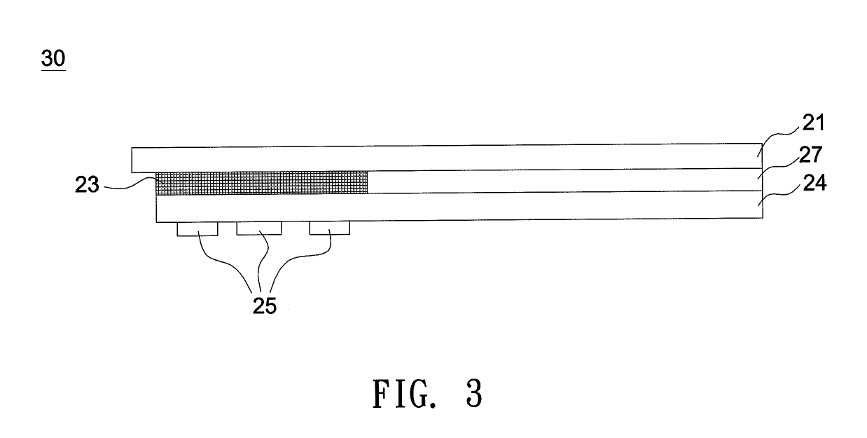

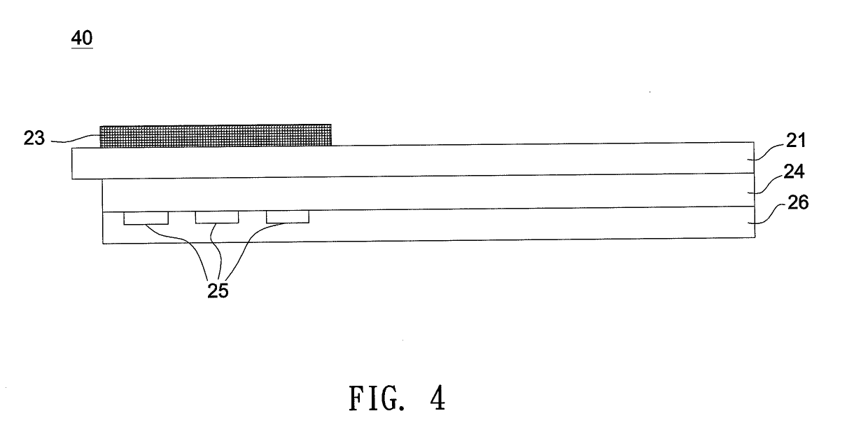

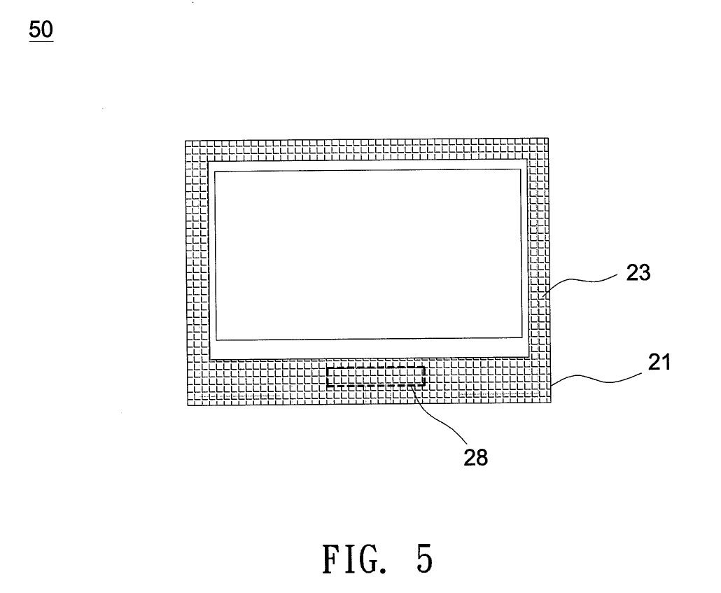

FIG. 3 shows a schematic diagram illustrating a surface capacitive touch panel according to another embodiment of the invention. As shown in FIG. 3, in the surface capacitive touch panel 30, the passivation layer 26 shown in FIG. 2B is omitted but the aforesaid effect is still achieved. FIG. 4 shows a schematic diagram illustrating a surface capacitive touch panel according to another embodiment of the invention. As shown in FIG. 4, in the surface capacitive touch panel 40, the decorative layer 23 is formed on another side of the transparent substrate 21 opposite the capacitive sensing electrode layer 24. That is, the decorative layer 23 may be formed on a touching face of the transparent substrate 21. FIG. 5 shows a schematic diagram illustrating a surface capacitive touch panel according to another embodiment of the invention. As shown in FIG. 5, at least one driver chip 28 is disposed on the decorative layer 23 of the surface capacitive touch panel 50 to form a chip-on-glass framework.

In the above embodiments, the decorative layer 23, the passivation layers 26 and 27, the capacitive sensing electrode layer 24, and the metal trace pattern layer 25 may be fabricated by at least one of the following processes: screen printing, sputtering, evaporation, dipping, and photolithography processes. In one embodiment, the thickness of the decorative layer 23 (such as a black matrix layer) is between 0.01 μm and 50 μm, the thickness of the passivation layer 26 is between 0.1 μm and 100 μm, the thickness of the passivation layer 27 is between 0.1 μm and 10 μm, the thickness of the capacitive sensing electrode layer 24 is between 0.1 μm and 1 μm, and the thickness of the metal trace pattern layer 25 is between 0.1 μm and 20

In one embodiment, the decorative layer 23 is, for example, a Cr/CrOₓ/SiO₂ inorganic coating and may be patterned by screening printing or a shadow mask. The capacitive sensing electrode layer 24 is, for example, made of indium tin oxide and formed by sputtering. The passivation layers 26 and 27 may be patterned by coating, exposing, developing, and post-baking processes. The material of the metal trace pattern layer 25 is, for example, silver or some other conductive metal and may be patterned by using a shadow mask.

In conventional designs, a black matrix layer is usually formed by screen printing black resin on a glass, and this may cause difficulties in reducing the thickness of the black matrix layer (layer thickness fails to decrease to less than 5 μm), difficulties in narrowing the panel border (border should be larger than 3 mm), difficulties in sustaining high temperature during post processing (incapable of sustaining more than 350° C.). Besides, the conventional black matrix layer is liable to crack under high moisture conditions and liable to deteriorate under an ultraviolet test. In comparison, according to an embodiment of the invention, an inorganic material such as Cr/CrOₓ/SiO₂ is used to form the decorative layer 23 by sputtering. Accordingly, it is easy to reduce the layer thickness (less than 1 μm), narrow the panel border (less than 1 mm), sustain high temperature (more than 350° C. during post processing). Further, the decorative layer 23 is not liable to crack under high moisture conditions and not liable to deteriorate under an ultraviolet test. Besides, since the process of sputtering an inorganic material is a common coating process, a special coating apparatus is not needed and thus fabrication costs are not increased.

Further, in conventional designs, a passivation layer is usually formed by screen printing transparent resin on an indium tin oxide layer, a black matrix layer or a silver paste, and this may cause difficulties in reducing the thickness of the passivation layer (layer thickness fails to decrease to less than 5 μm), cause an uneven thickness distribution, and influence electrical fields. In comparison, according to an embodiment of the invention, since the passivation layers 26 and 27 are patterned by coating, exposing, developing, and post-baking processes, their thicknesses may be easily reduced (less than 1 μm) and a uniform thickness distribution is achieved without affecting electric fields. Similarly, since the above fabrication processes such as exposure and developing processes are common semiconductor fabrication processes, a special apparatus for semiconductor fabrication is not needed and thus fabrication costs are not increased.

Besides, in conventional designs, a metal trace pattern layer is usually formed by screen printing silver paste, and this may cause difficulties in reducing the line width (line width fails to decrease to less than 1 mm), difficulties in narrowing the panel border (border should be larger than 3 mm), and difficulties in reducing the surface resistance of a conductive silver paste (surface resistance fails to decrease to less than 1 Ω/sq). In comparison, according to an embodiment of the invention, since the metal trace pattern layer is formed by metal sputtering and patterned by using a shadow mask, the line width is reduced (less than 20 μm), the panel border is narrowed without any restriction, and the surface resistance of a conductive silver paste is considerably reduced (less than 0.04 Ω/sq). Similarly, since the sputtering process is a common coating process, a special coating apparatus is not needed and thus fabrication costs are not increased.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the present disclosure is intended to be dedicated to the public regardless of whether the element or component is explicitly recited in the following claims.

What is claimed is:

1. A surface capacitive touch panel, comprising:
a transparent substrate;
a decorative layer formed on a surface of the transparent substrate;
a capacitive sensing electrode layer formed on a first side of the transparent substrate;
a metal trace pattern layer formed on the capacitive sensing electrode layer, wherein the decorative layer is disposed at a position substantially overlapping the metal trace pattern layer to shadow metal traces of the metal trace pattern layer; and
a passivation layer formed between the transparent substrate and the capacitive sensing electrode layer.

2. The surface capacitive touch panel as claimed in claim 1, wherein the decorative layer is a black matrix layer and the metal traces are silver traces.

3. The surface capacitive touch panel as claimed in claim 1, wherein the metal trace pattern layer is formed on the periphery of the capacitive sensing electrode layer.

4. The surface capacitive touch panel as claimed in, claim 1, wherein the decorative layer is made of at least one of diamond-like carbon, ceramics, ink, and photo resists.

5. The surface capacitive touch panel as claimed in claim 1, wherein the decorative layer is formed on the first side of the transparent substrate and disposed between the transparent substrate and the capacitive sensing electrode layer.

6. The surface capacitive touch panel as claimed in claim 1, wherein the decorative layer is formed on a second side of the transparent substrate opposite the first side.

7. The surface capacitive touch panel as claimed in claim 1, further comprising:
a passivation layer formed on the metal trace pattern layer.

8. The surface capacitive touch panel as claimed in claim 1, further comprising:
at least one driver chip disposed on the decorative layer.

9. A method for fabricating a surface capacitive touch panel, comprising the steps of:
providing a transparent substrate;
forming a coating on a surface of the transparent substrate and patterning the coating to form a decorative layer;
forming a capacitive sensing electrode layer on the transparent substrate;
forming a metal trace pattern layer on the capacitive sensing electrode layer, wherein the decorative layer is disposed at a position substantially overlapping the metal trace pattern layer to shadow metal traces of the metal trace pattern layer; and
forming a first passivation layer between the transparent substrate and the capacitive sensing electrode layer.

10. The method as claimed in claim 9, wherein the step of forming the decorative layer comprises:
sputtering an inorganic material on the surface of the transparent substrate to form an inorganic coating; and
patterning the inorganic coating.

11. The method as claimed in claim 10, wherein the inorganic material comprises Cr, CrOₓ, and SiO₂.

12. The method as claimed in claim 9, wherein the step of forming a metal trace pattern layer comprises sputtering a metal layer and patterning the metal layer by using a shadow mask.

13. The method as claimed in claim 9, wherein the first passivation layer is patterned by coating, exposing, developing, and post-baking, and the thickness of the first passivation layer is between 0.1 μm and 10 μm.

14. The method as claimed in claim 9, further comprising:
forming a second passivation layer on the metal trace pattern layer to cover the metal trace pattern layer.

15. The method as claimed in claim 14, wherein the second passivation layer is patterned by coating, exposing, developing, and post-baking, and the thickness of the second passivation layer is between 0.1 μm and 100 μm.

16. The method as claimed in claim 9, wherein the thickness of the decorative layer is between 0.01 μm and 50 μm.

17. The method as claimed in claim 9, wherein the thickness of the capacitive sensing electrode layer is between 0.1 μm and 1 μm.

18. The method as claimed in claim 9, wherein the thickness of the metal trace pattern layer is between 0.1 μm and 20 μm.
